(19) United States
(12) Patent Application Publication
(10) Pub. No.: US 2021/0362492 A1
(43) Pub. Date: Nov. 25, 2021

(54) TEMPERATURE SENSING

(71) Applicant: Hewlett-Packard Development Company, L.P., Spring, TX (US)

(72) Inventors: James Michael Gardner, Corvallis, OR (US); Daryl E. Anderson, Corvallis, OR (US); Eric Thomas Martin, Corvallis, OR (US); Rogelio Cicili, San Diego, CA (US)

(73) Assignee: Hewlett-Packard Development Company, L.P., Spring, TX (US)

(21) Appl. No.: 17/058,692

(22) PCT Filed: Nov. 16, 2018
(86) PCT No.: PCT/US2018/061587

§ 371 Date: Nov. 25, 2020

(51) Int. Cl. B41J 2/045; G01K 7/01; G01K 1/02

(52) U.S. Cl. CPC B41J 2/04563; G01K 7/01; H03F 3/45; B41J 2/0458; B41J 2/04541; G01K 1/026

(57) ABSTRACT

Examples of a fluidic die for temperature sensing are described herein. In some examples, a fluidic die may include a plurality of thermal sense modules. In some examples, each of the thermal sense modules includes a diode connected between a first switch and a second switch. In some examples, the fluidic die includes a differential amplifier to output a temperature voltage signal. In some examples, a first input of the differential amplifier is connected to the first switch of each of the thermal sense modules and a second input of the differential amplifier is connected to the second switch of each of the thermal sense modules.

### BACKGROUND

Fluid ejection systems may be used to emit a fluid. For example, printing devices provide a user with a physical representation of a document by printing a digital representation of a document onto a print medium. The printing devices may include a number of fluidic dies used to eject ink or other printable material onto the print medium to form an image. In some examples, a fluidic die may deposit fluid droplets onto the print medium using a number of fluidic actuators (e.g., resistive elements) within the fluidic die. In other examples, a fluidic actuator may move a fluid on the fluidic die.

### BRIEF DESCRIPTION OF THE DRAWINGS

FIG. 1A is a block diagram of an example of a fluidic die;

FIG. 1B is a simplified block diagram of an example of a fluid ejection system incorporating a fluidic die;

FIG. 2A is a circuit diagram illustrating an example of fluidic die circuitry;

FIG. 2B is a circuit diagram illustrating an example of a thermal sense module;

FIG. 3A is a circuit diagram illustrating an example of fluidic die circuitry;

FIG. 3B is a circuit diagram illustrating an example of a thermal sense module; and

FIG. 4 is a flow diagram illustrating an example of a method for temperature sensing.

Throughout the drawings, identical reference numbers designate similar, but not necessarily identical, elements. The figures are not necessarily to scale, and the size of some parts may be exaggerated to more clearly illustrate the example shown. Moreover, the drawings provide examples and/or implementations consistent with the description; however, the description is not limited to the examples and/or implementations provided in the drawings.

### DETAILED DESCRIPTION

The description provides examples of systems, methods, and apparatus to implement structures for thermal zone and/or global temperature measurement with differential sensing. Some examples may help to overcome errors in measuring zonal temperatures which result from variation in offsets in per zone amplifiers and/or sense currents.

In some examples, thermal sensing circuitry may include a global current source that supplies a current to the circuitry, and a thermal sense module in each thermal zone that is connected to the current source. An example of the thermal sense module may include a selection switch (e.g., thermal zone selection field-effect transistor (FET)), a diode stack, and switches (e.g., FETs) that connect the (differential) voltage developed across the diode stack to lines that feed that voltage to a global differential amplifier. In some examples, having one differential amplifier reduces or eliminates a cause of zone-to-zone offset error. In some examples, circuitry may be added to shift the temperature voltage signal to a range that is within (e.g., centered) in an analog-to-digital converter (ADC) input range. In some examples, a current may be forced into a diode stack of a selected zone, the voltage across the stack may be coupled to a differential amplifier, and/or the resulting temperature signal may be utilized.

In the following description, for purposes of explanation, numerous specific details are set forth in order to provide a thorough understanding of the present systems and methods. As may be appreciated, the present apparatus, systems, and methods may be practiced without these specific details. Reference in the specification to “an example” or similar language means that a particular feature, structure, or characteristic described in connection with that example is included as described, but may not be included in other examples.

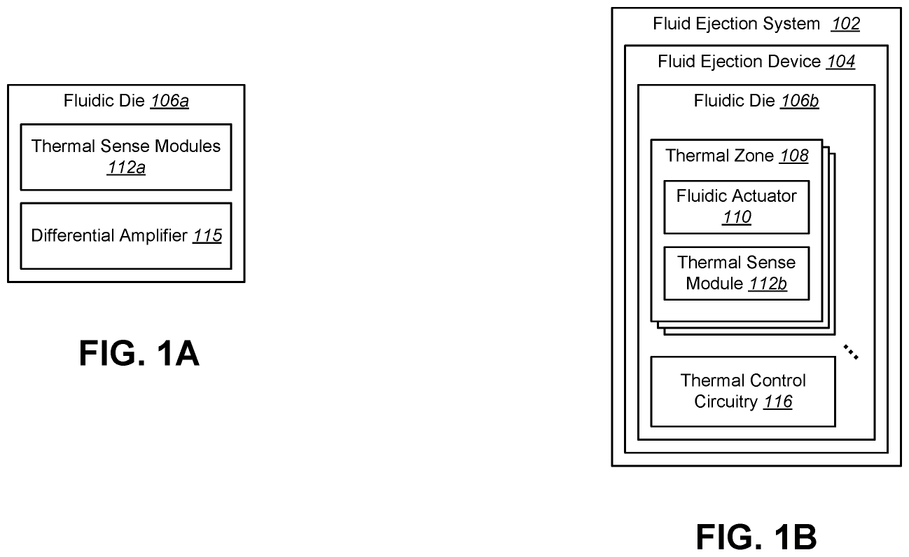

FIG. 1A is a block diagram of an example of a fluidic die 106a. The fluidic die 106a may include a plurality of thermal sense modules 112a. A thermal sense module 112a is circuitry for sensing or measuring temperature. In some examples, each of the thermal sense modules 112a may include a diode connected between a first switch and a second switch.

In some examples, the fluidic die 106a includes a differential amplifier 115. The differential amplifier 115 may output a temperature voltage signal. For example, a first input of the differential amplifier may be connected to the first switch of each of the thermal sense modules 112a and a second input of the differential amplifier may be connected to the second switch of each of the thermal sense modules 112a. As described in greater detail herein, the differential amplifier 115 may output a temperature voltage signal corresponding to the thermal sense module(s) 112a.

FIG. 1B is a simplified block diagram of an example of a fluid ejection system 102 incorporating a fluidic die 106b. The fluid ejection system 102 may include various hardware components. For example, among these hardware components may be a number of processors, a number of data storage devices, a number of peripheral device adapters, and a number of network adapters (not shown). These hardware components may be interconnected through the use of a number of busses and/or network connections.

In some examples, the fluid ejection system 102 may be a two-dimensional (2D) printer (e.g., thermal inkjet printer, piezoelectric inkjet printer, etc.) In other examples, the fluid ejection system 102 may be a three-dimensional (3D) printer. In other examples, the fluid ejection system 102 may correspond to pharmaceutical dispensation devices, lab-on-a-chip devices, fluidic diagnostic circuits, and/or other such devices in which small volumes (e.g., microliters, picoliters, etc.) of fluid may be conveyed, analyzed, and/or dispensed.

The fluid ejection system 102 also includes a number of fluid ejection devices 104. Although one fluid ejection device 104 is depicted in the example of FIG. 1 B, any number of fluid ejection devices 104 may exist within the fluid ejection system 102. The fluid ejection devices 104 may be fixed or scanning fluid ejection devices. The fluid ejection devices 104 may be coupled to the processor of the fluid ejection system 102 via a bus. The fluid ejection devices 104 may receive print data in the form of a print job. For example, the print data may be used by the fluid ejection devices 104 to produce a physical print representing the print job.

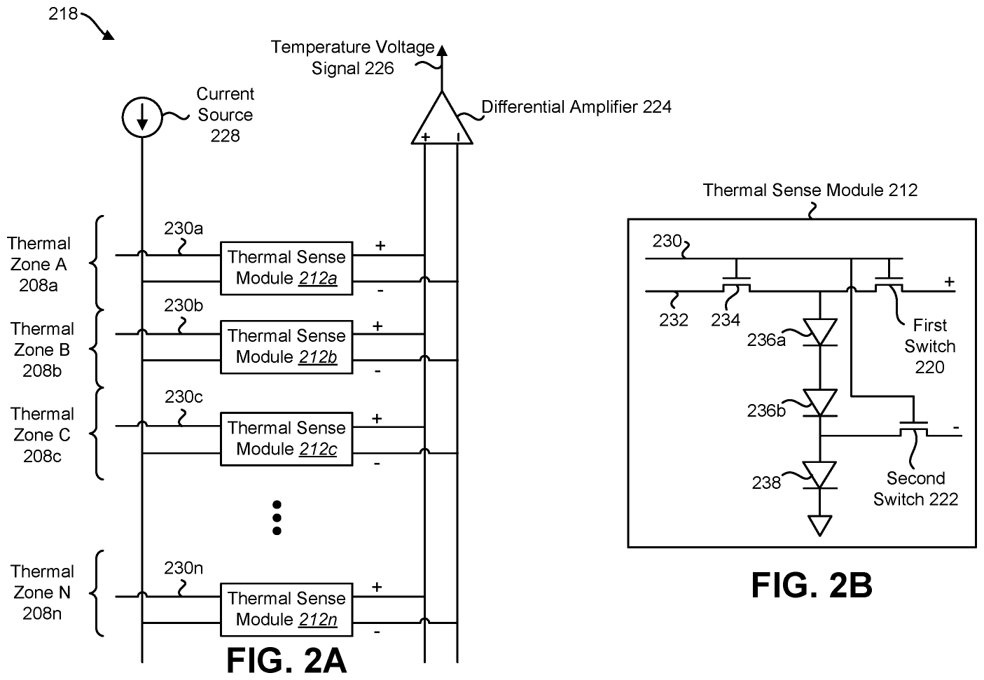

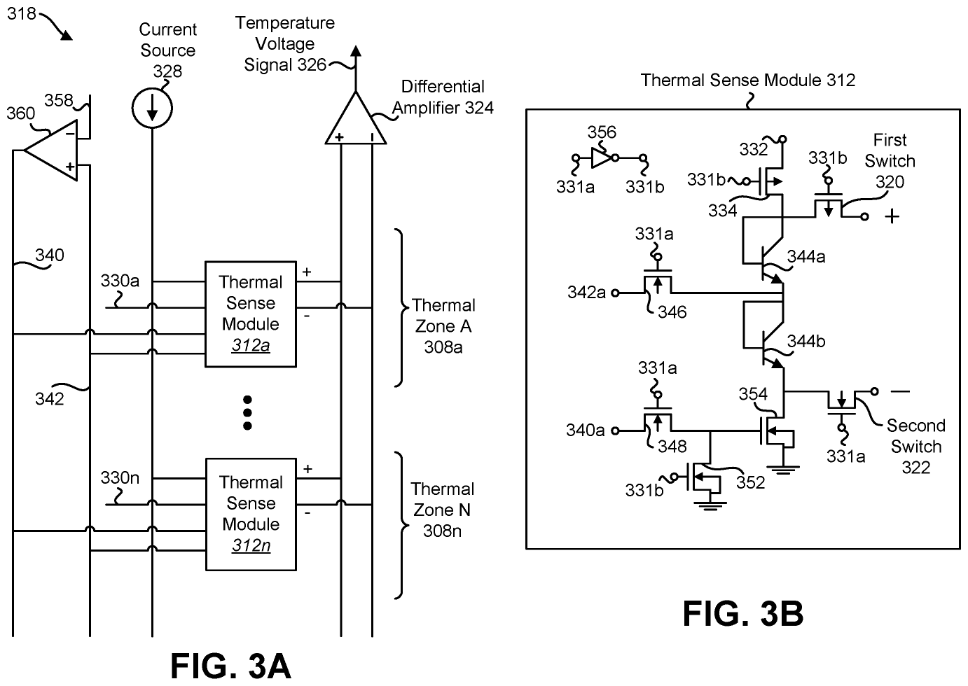

Each fluid ejection device 104 includes a number of fluidic dies 106b. A fluidic die is a structure for dispensing fluid. Although one fluidic die 106b is depicted in the example of FIG. 1B, any number of fluidic dies 106b may exist within the fluid ejection device 104. A fluidic die 106b may include multiple thermal zones 108. Examples of fluidic die circuitry are described in connection with FIGS. 2A-2B and FIGS. 3A-3B. In some implementations, the fluidic die 106b described in connection with FIG. 1B may be an example of the fluidic die 106a described in connection with FIG. 1A.

A thermal zone is an area of the fluidic die 106b in which temperature is to be sensed and/or measured. In some examples, each thermal zone 108 may include a number of fluidic actuators 110. A fluidic actuator 110 is a device to move (e.g., eject, expel) fluid from a fluid chamber of the fluidic die 106b. A fluid chamber is a container or volume that holds fluid. In some examples, the thermal zones 108 may include a single fluidic actuator 110 or multiple fluidic actuators 110. A primitive is a structure for printing that may include circuitry and a nozzle or nozzles for expelling fluid. In some implementations, a number of fluidic actuators 110 may be grouped into a primitive or primitives. It should be noted that there may be any number of fluidic actuators 110, nozzles, primitives, or parts of primitives in a thermal zone 108. In some examples, a thermal zone 108 may not include a fluidic actuator 110 or primitive and/or may be independent of a fluidic actuator 110 or primitive. In some implementations, there may be an integer number of primitives in a thermal zone 108 (e.g., 8).

In some examples, the fluidic actuator 110 may be an ejecting actuator. An ejecting actuator may correspond to a fluidic actuator 110 disposed in an ejection chamber, where the ejection chamber may be fluidically coupled to a nozzle. Accordingly, by electrically actuating an ejection actuator, a drop of fluid may be ejected via the nozzle fluidically coupled to the ejection chamber. For instance, a fluid (e.g., ink) may flow through the fluidic die 106b to a fluidic actuator 110. In some examples, the fluidic actuator 110 may deposit the fluid on a print medium. In other examples, the fluidic actuator 110 may eject the fluid without a print medium. Examples of the fluidic die 106b that eject fluid are fluid ejection dies. In some examples, the fluidic die 106b and/or a fluid ejection die may be or may be included in a print head.

In some examples, the fluidic actuator 110 may use heat to cause the fluid to exit the fluidic actuator 110 (through a nozzle, for instance). For instance, the fluidic actuator 110 may generally refer to a resistor (e.g., thermal resistor or a piezoelectric resistor) disposed in an ejection chamber.

In other examples, the fluidic actuator 110 may be a non-ejecting actuator. For example, the fluidic actuator 110 may be a micro-pump that moves fluid on the fluidic die 106b. In such examples, a fluidic actuator 110 in the form of a micro-pump may be disposed in a microfluidic channel. Accordingly, actuation of the fluidic actuator 110 in such examples may cause displacement of fluid in the microfluidic channel.

As used herein, a “fluid ejection device” and a “fluidic die” mean that part of a fluid ejection system 102 that dispenses fluid from one or more openings. A fluid ejection device includes a number of fluidic dies. “Fluid ejection device” and “fluidic die” are not limited to printing with ink and other printing fluids but may also include dispensing of other fluids and/or for uses other than printing.

In some examples, a thermal zone 108 may include at least one thermal sense module 112b. A thermal sense module 112b is circuitry for sensing or measuring temperature. In some examples, the thermal sense module 112b may include a diode, a plurality of diodes (e.g., a diode stack), a diode-connected transistor, or a plurality of diode-connected transistors. In some examples, the thermal sense module 112b may span or travel through multiple thermal zones 108. The thermal sense module 112b may be utilized to measure the temperature of the thermal zone 108. For example, it may be beneficial to know the temperature of the fluidic actuator(s) 110 (e.g., nozzles) in a given thermal zone 108. For example, the temperature may be utilized to adjust fluid actuation.

In some examples, the fluidic die 106b includes multiple thermal zones 108, where each thermal zone includes a thermal sense module 112b. For example, a plurality of thermal sense modules 112b may be coupled in parallel with each other. In some examples, the fluidic die 106b may include a current source coupled to a plurality of thermal sense modules 112b. For example, the thermal sense modules 112b may be coupled to a single current source to drive the plurality of thermal sense modules 112b. For instance, a single current source may be utilized for all thermal zones 108 and/or thermal sense modules 112b.

In some examples, each thermal sense module 112b may include a selection switch. A switch is an electronic device for selectively connecting or disconnecting an electrical path. Examples of the selection switch include transistors and metal-oxide semiconductor field-effect transistors (MOSFETs). The selection switch corresponding to a thermal sense module 112b may be activated in order to measure temperature corresponding to that thermal sense module 112b and/or corresponding to a particular thermal zone 108.

In some examples, each thermal sense module 112b may include switches (e.g., output switches). For instance, each thermal sense module 112b may include a pair of switches. One switch of the pair of switches may be coupled to a first side or end of the diode(s) or diode-connected transistor(s), while the other switch of the pair of switches may be coupled to a second side or end of the diode(s) or diode-connected transistor(s). Examples of the switches include transistors and metal-oxide semiconductor field-effect transistors (MOSFETs).

In some examples, the fluidic die 106b includes a differential amplifier. The differential amplifier is an electronic device that amplifies a difference in voltage between inputs of the differential amplifier. The inputs of the differential amplifier may be coupled to the switches. For example, a pair of inputs of the differential amplifier may be coupled to each pair of switches. For instance, a first input of the differential amplifier may be coupled to a first switch of the pair of switches and a second input of the differential amplifier may be coupled to a second switch of the pair of switches (for each pair of switches).

The differential amplifier may output a temperature voltage signal for a thermal zone 108 or for thermal zones 108. For example, each pair of switches may be activated to produce a temperature voltage signal corresponding to each thermal zone 108. For instance, a pair of switches may be activated that correspond to one thermal sense module 112b. A first switch may provide a voltage from a first side or end of the diode(s) or diode-connected transistor(s) to a first input of the differential amplifier and a second switch may provide a voltage from a second side or end of the diode(s) or diode-connected transistor(s) to a second input of the differential amplifier. The differential amplifier may measure the difference between the two voltages to provide the temperature voltage signal corresponding to that thermal sense module 112b and/or thermal zone 108. This procedure may be repeated for each thermal sense module 112b and/or thermal zone 108 to determine a temperature for each thermal sense module 112b and/or thermal zone 108.

In some examples, multiple selection switches may be activated to measure an average temperature over multiple thermal sense modules 112b and/or thermal zones 108. For example, a set of selection switches (e.g., all or a subset of a plurality of selection switches) may be activated to measure an average temperature. For instance, a set of selection switches corresponding to a set of thermal sense modules 112b and/or thermal zones 108 (e.g., all or a subset of thermal sense modules 112b and thermal zones 108) may be activated to output an average temperature voltage signal over the set of thermal sense modules 112b and/or thermal zones 108.

In some examples, the fluidic die 106b may include thermal control circuitry 116. The thermal control circuitry 116 may control thermal sensing for multiple thermal zones 108 and/or thermal sense modules 112b. For example, the thermal control circuitry 116 may selectively activate a selection switch(s) and/or other switches (e.g., output switches) of a thermal sense module 112b to control temperature measurement for one thermal zone 108 (e.g., one thermal sense module 112b), temperature measurement for a sequence of thermal zones 108 (e.g., a sequence of thermal sense modules 112b), and/or average temperature measurement over multiple thermal zones 108 (e.g., multiple thermal sense modules 112b). In some examples, the thermal control circuitry 116 may make a thermal control decision or decisions based on a temperature voltage signal.

In some examples, the differential amplifier may be included in the thermal control circuitry 116. For example, a single differential amplifier may be coupled to all of the thermal sense modules 112b. In some examples, a current source may be included in the thermal control circuitry 116. For example, a single current source may be coupled to all of the thermal sense modules 112b. The thermal control circuitry 116 may control the current of the current source. For example, the amount of current, or a current level may be controlled based on a number of thermal sense modules 112b and/or thermal zones 108 being measured. For instance, in order to measure a temperature of a single thermal zone 108 (e.g., one thermal sense module 112b), the current of the current source may be set to a value. In order to measure an average temperature of all thermal zones 108 (e.g., over all thermal sense modules 112b), the current of the current source may be set to a different value. Other values may be utilized to measure an average temperature for other combinations of multiple thermal zones 108.

FIG. 2A is a circuit diagram illustrating an example of fluidic die circuitry 218. The fluidic die circuitry 218 may be an example of, or may be included in an example of, the fluidic die 106b described in connection with FIG. 1B. The fluidic die circuitry 218 may include a current source 228 and a differential amplifier 224. In some examples, there may be one current source 228 (e.g., a global current source) for all of the thermal sense modules 212a-n of the fluidic die circuitry 218. For instance, the current source 228 may be a fixed current source that is used in common for measuring all thermal zones 208a-n. A wire may communicate the current down a column to the thermal zones 208a-n. In some examples, there may be one differential amplifier 224 (e.g., a global differential amplifier) for all of the thermal sense modules 212a-n of the fluidic die circuitry 218.

In some examples, the fluidic die circuitry 218 may include a plurality of thermal sense modules 212a-n. In some examples, the thermal sense modules 212a-n may be connected in parallel with each other. A voltage measurement from a thermal sense module may vary based on temperature. Accordingly, variations in voltage over a thermal sense module may be utilized to determine a temperature of the thermal sense module. In some examples, each thermal zone 208a-n may include a thermal sense module 212a-n that is connected in parallel with another thermal sense module 212a-n in another thermal zone 208a-n. A thermal zone is an area or region of a fluidic die.

In some examples, each of the thermal sense modules 212a-n corresponds to a thermal zone 208a-n. The differential amplifier 224 may be a single differential amplifier 224 that may output a differential voltage (e.g., a temperature voltage signal 226) for each of the thermal zones 208a-n.

In some examples, each thermal sense module 212a-n may be coupled to the current source 228. In some examples, the current source 228 may drive the plurality of thermal sense modules 212a-n. For instance, the current source 228 may be a single current source to drive the plurality of thermal sense modules 212a-n.

A selection line 230a-b may be coupled to each thermal sense module 212a-n. Each of the selection lines 230a-n may control whether each corresponding thermal sense module 212a-n and/or thermal zone 208a-n is selected for temperature measurement. For example, thermal control circuitry may apply a signal (e.g., voltage) to one of the selection lines 230a-n or multiple of the selection lines 230a-n to activate one of the thermal sense modules 212a-n or multiple of the thermal sense modules 212a-n. For instance, one thermal zone may be selected to be measured for temperature (at a time), or multiple thermal zones may be selected to be measured for temperature.

In some examples, the fluidic die circuitry 218 may include a plurality of selection switches. For instance, each of the thermal sense modules 212a-n may include a selection switch coupled a corresponding selection line 230a-n. In some examples, selecting a thermal zone 208a-n may be achieved by enabling a transistor (e.g., field-effect transistor (FET)), which transmits the current through the transistor and into circuits in the selected thermal sense module 212a-n.

In some examples, a set (e.g., multiple or all) of the plurality of selection switches corresponding to a selected set (e.g., multiple or all) of the thermal sense modules 212a-n may be activated to output an average temperature voltage signal 226 over the selected set of thermal sense modules. In some examples, a current of the current source 228 may be set based on a number of the selected set of thermal sense modules. In some examples, for average temperature measurement across multiple thermal zones 208a-n, the current may be forced into multiple thermal zones 208a-n in parallel. The set current may be set to a different level than when a single thermal zone is being measured.

In an example, activating a thermal sense module 212a may cause current from the current source 228 to flow through the thermal sense module 212a. The current may flow through a component or components (e.g., diode(s), diode-connected transistor(s)) of the thermal sense module 212a, thereby producing a voltage difference over the component or components. Voltages from the thermal sense module 212a may be provided or output to the differential amplifier 224, which may measure a difference between the voltages to produce a temperature voltage signal 226.

FIG. 2B is a circuit diagram illustrating an example of a thermal sense module 212. The thermal sense module 212 may be one example of the thermal sense modules 212a-n described in connection with FIG. 2A. For instance, a plurality of the thermal sense modules 212 described in FIG. 2B may be implemented as the thermal sense modules 212a-n described in connection with FIG. 2A.

In some examples, the thermal sense module 212 may include a diode or diodes 236a-b connected between a first switch 220 and a second switch 222. Examples of the first switch 220 and the second switch 222 may include field-effect transistors (FETs). The first switch 220 and the second switch 222 may be referred to as output switches. For example, a first input of the differential amplifier 224 may be connected to a first switch 220 (of each of the thermal sense modules 212a-n, for instance) and a second input of the differential amplifier 224 may be connected to a second switch 222 (of each of the thermal sense modules 212a-n, for instance).

In some examples, a first terminal of the first switch 220 may be connected to a first side of a component or components (e.g., diode(s) 236a-b or diode-connected transistor(s)). In some examples, a first terminal of the second switch 222 may be connected to a second side of a component or components (e.g., diode(s) 236a-b or diode-connected transistor(s)). In some examples, a first input of the differential amplifier 224 is connected to a second terminal of the first switch 220. A second input of the differential amplifier 224 may be connected to a second terminal of the second switch 222.

The thermal sense module 212 may include a selection switch 234 to be activated to force a current 232 through the component or components (e.g., diode(s) 236a-b or diode-connected transistor(s)). For example, the selection line 230 may activate the selection switch 234 to allow the current 232 to flow through a diode or diodes 236a-b. In some examples, a gate of the first switch 220, a gate of the second switch 222, and a gate of the selection switch 234 may be coupled to the selection line 230. Accordingly, the first switch 220, the second switch 222, and the selection switch 234 may be activated concurrently in some implementations. In some examples, the first switch 220, the second switch 222, and/or the selection switch 234 may be individually addressable (e.g., selectable).

As illustrated in the example of FIG. 2B, multiple diodes 236a-b may be connected between the first switch 220 and the second switch 222. In some examples, a diode 238 (or diodes) may be connected between the second switch 222 and ground. The diode 238 may be implemented to raise the voltage at the bottom (e.g., cathode) of the diodes 236a-b above ground. This approach may be helpful in the design of the differential amplifier 224. In other examples, the second switch 222 may be connected to ground without an intervening diode. In some examples, in the thermal sense module 212, the current flows into the anode of a stack of a series of connected diodes 236a-b. The current flows out the cathode of the stack of diodes 236a-b, and may flow through another diode 238 to ground. The number of diodes 236a-b in the stack may be a design consideration related to signal-to-noise ratio (SNR) and design of the differential amplifier 224.

In some examples, the first switch 220 and the second switch 222 may be activated to output voltages for the thermal sense modules 212. In an example, the thermal sense module 212 of FIG. 2B may be the thermal sense module 212a of the fluidic die circuitry 218 of FIG. 2A. In this example, the selection switch 234, the first switch 220, and the second switch 222 may be activated to output a temperature voltage signal 226 for thermal zone A 208a. Other respective selection switches and pairs of first switches and second switches may be activated to output a temperature voltage signal 226 for other thermal sense modules 212b-n (e.g., for thermal zones B-N 208b-n).

In some examples, the current flowing through the diodes 236a-b results in a voltage across the diodes 236a-b that is approximately linear with the corresponding thermal zone's temperature. A selection signal on the selection line 230 may also connect the top and bottom of the diodes 236a-b to two wires in the column, via the first switch 220 and the second switch 222 (e.g., FETs). These two wires may communicate the voltages from the top and bottom of the diodes 236a-b (e.g., diode stack) to the differential amplifier 224, which is connected to the selected zone. The differential amplifier 224 may amplify the voltage difference across the diodes 236a-b, and may output the temperature voltage signal 226. In some examples, the temperature voltage signal 226 may be a single-ended voltage (relative to ground), which represents the corresponding thermal zone's temperature.

In some examples, when diodes vary in temperature, their average temperature response is not identical to when all diodes are at the same temperature. This property may be utilized for hot spot detection for thermal runaway. For example, reading diodes (from multiple thermal zones) in parallel may return a voltage close to an average when the delta is small between the diodes, but the voltage may become dominated by the hottest diode as the temperature delta becomes larger. In this way, reading diodes in parallel may provide an average temperature sensor, while also having the ability to identify hot spots on a fluidic die. In some examples, operation may be slowed or stopped in response to detecting a hot spot.

FIG. 3A is a circuit diagram illustrating an example of fluidic die circuitry 318. The fluidic die circuitry 318 may be an example of, or may be included in an example of, the fluidic die 106b described in connection with FIG. 1B. The fluidic die circuitry 318 may include a current source 328 and a differential amplifier 324. In some examples, there may be one current source 328 (e.g., a global current source) for all of the thermal sense modules 312a-n of the fluidic die circuitry 318. In some examples, there may be one differential amplifier 324 (e.g., a global differential amplifier) for all of the thermal sense modules 312a-n of the fluidic die circuitry 318.

In some examples, the fluidic die circuitry 318 may include a plurality of thermal sense modules 312a-n. In some examples, the thermal sense modules 312a-n may be connected in parallel to each other. A voltage measurement from a thermal sense module may vary based on temperature. Accordingly, variations in voltage over a thermal sense module may be utilized to determine a temperature of the thermal sense module. In some examples, each thermal zone 308a-n may include a thermal sense module 312a-n that is connected in parallel with another thermal sense module 312a-n in another thermal zone 308a-n.

In some examples, each of the thermal sense modules 312a-n corresponds to a thermal zone 308a-n. The differential amplifier 324 may be a single differential amplifier 324 that may output a differential voltage (e.g., a temperature voltage signal 326) for each of the thermal zones 308a-n.

In some examples, each thermal sense module 312a-n may be coupled to the current source 328. In some examples, the current source 328 may drive the plurality of thermal sense modules 312a-n. For instance, the current source 328 may be a single current source to drive the plurality of thermal sense modules 312a-n.

A selection line 330a-n may be coupled to each thermal sense module 312a-n. Each of the selection lines 330a-n may control whether each corresponding thermal sense module 312a-n and/or thermal zone 308a-n is selected for temperature measurement. For example, thermal control circuitry may apply a signal (e.g., voltage) to one of the selection lines 330a-n or multiple of the selection lines 330a-n to activate one of the thermal sense modules 312a-n or multiple of the thermal sense modules 312a-n.

In some examples, the fluidic die circuitry 318 may include a plurality of selection switches. For instance, each of the thermal sense modules 312a-n may include a selection switch coupled to a corresponding selection line 330a-n. A set (e.g., multiple or all) of the plurality of selection switches corresponding to a selected set (e.g., multiple or all) of the thermal sense modules 312a-n may be activated to output an average temperature voltage signal 326 over the selected set of thermal sense modules. In some examples, a current of the current source 328 may be set based on a number of the selected set of thermal sense modules.

In an example, activating a thermal sense module 312a may cause current from the current source 328 to flow through the thermal sense module 312a. The current may flow through a component or components (e.g., diode(s), diode-connected transistor(s)) of the thermal sense module 312a, thereby producing a voltage difference over the component or components. Voltages from the thermal sense module 312a may be provided or output to the differential amplifier 324, which may measure a difference between the voltages to produce a temperature voltage signal 326.

In some examples, the fluidic die circuitry 318 may include a feedback amplifier 360 (e.g., a unity gain amplifier). The feedback amplifier 360 may be utilized to set a common mode voltage for the thermal sense modules 312a-n. For example, one input of the feedback amplifier 360 may by coupled to a common mode set voltage 358. The common mode set voltage 358 indicates or sets a target voltage for a common mode of a thermal sense module or modules 312a-n. Another input of the feedback amplifier 360 may be coupled to a common mode sense signal 342 from the thermal sense module(s) 312a-n. The common mode sense signal 342 is a signal indicating a common mode voltage of the thermal sense module or modules 312a-n. The output of the feedback amplifier 360 may provide a common mode control signal 340 to the thermal sense module(s) 312a-n. The common mode control signal 340 is an electronic signal that controls the common mode voltage of the thermal sense module or modules 312a-n. For example, the feedback amplifier 360 may drive the common mode control signal 340 in order to match the common mode sense signal 342 to the common mode set voltage 358. In some examples, the common mode control signal 340 may control a selected thermal sense module or modules 312a-n and/or the common mode sense signal 342 may be provided by the selected thermal sense module or modules 312a-n.

FIG. 3B is a circuit diagram illustrating an example of a thermal sense module 312. The thermal sense module 312 may be one example of the thermal sense modules 312a-n described in connection with FIG. 3A. For instance, a plurality of the thermal sense modules 312 described in FIG. 3B may be implemented as the thermal sense modules 312a-n described in connection with FIG. 3A.

In some examples, the thermal sense module 312 may include a diode-connected transistor or diode-connected transistors 344a-b connected between a first switch 320 and a second switch 322. The first switch 320 and the second switch 322 may be referred to as output switches. For example, a first input of the differential amplifier 324 may be connected to a first switch 320 (of each of the thermal sense modules 312a-n, for instance) and a second input of the differential amplifier 324 may be connected to a second switch 322 (of each of the thermal sense modules 312a-n, for instance).

In some examples, a first terminal of the first switch 320 may be connected to a first side of a component or components (e.g., diode-connected transistor(s) 344a-b). In some examples, a first terminal of the second switch 322 may be connected to a second side of a component or components (e.g., diode-connected transistor(s) 344a-b). In some examples, a first input of the differential amplifier 324 is connected to a second terminal of the first switch 320. A second input of the differential amplifier 324 may be connected to a second terminal of the second switch 322.

In some examples, a selection line 331a is provided to the thermal sense module 312. The selection line 331a may be an example of the selection lines 330a-n described in connection with FIG. 3A. The selection line 331a may provide a selection signal to select (e.g., activate) the thermal sense module 312. As illustrated in FIG. 3B, the thermal sense module 312 may include an inverter 356 in some examples. The selection line 331a may be provided to the inverter 356, which may produce a signal for a negative selection line 331b. The selection line 331a and the negative selection line 331b may be utilized to activate or deactivate the thermal sense module 312.

The thermal sense module 312 may include a selection switch 334 to be activated to force a current 332 (e.g., bias current) through the component or components (e.g., diode-connected transistor(s) 344a-b). For example, the negative selection line 331b may activate the selection switch 334 to allow the current 332 to flow through a diode-connected transistor or diode-connected transistors 344a-b. An example of the diode-connected transistor 344a is a diode-connected bipolar junction transistor (BJT). For example, a base may be connected to a collector of a diode-connected transistor.

As illustrated in the example of FIG. 3B, multiple diode-connected transistors 344a-b may be connected between the first switch 320 and the second switch 322. For instance, the thermal sense module 312 may include a first diode-connected transistor 344a and a second diode-connected transistor 344b coupled in series with the first diode-connected transistor 344a. In some examples, a first transistor 354 may be connected between the second switch 322 and ground.

In some examples, a common mode sense switch 346 may be connected between the diode-connected transistors 344a-b. The common mode sense switch 346 may be activated by the selection line 331a when the thermal sense module 312 is selected, which may allow the thermal sense module 312 to provide a common mode sense signal 342a.

In some examples, a common mode control switch 348 may be connected to a gate of the first transistor 354 that is connected between the second switch 322 and ground. The common mode control switch 348 may be activated by the selection line 331a when the thermal sense module 312 is selected, which may allow the common mode control line 340a to set the common mode voltage of the thermal sense module 312 (between the diode-connected transistors 344a-b, for instance).

In some examples, a second transistor 352 may be connected between the common mode control switch 348 and the first transistor 354. The second transistor 352 may be activated by the negative selection line 331b when the thermal sense module 312 is selected. For example, instead of a diode, a feedback amplifier 360 for setting the common mode voltage, in conjunction with a common mode voltage-shifting transistor (e.g., FET), may set the common mode voltage of the differential signal. This approach may utilize a common mode control signal and a common mode sense signal for each thermal sense module 312a-n.

In some examples, the common mode set voltage 358 may be applied to an inverting terminal of the feedback amplifier 360. The feedback amplifier 360 may drive the common mode control signal 340 such that the difference between the common mode set voltage 358 and the common mode sense signal 342 (e.g., common mode sense signal 342a of a selected thermal sense module 312) is zero. When the thermal sense module 312 is not selected, the selection switch 334, common mode sense switch 346, common mode control switch 348, first switch 320, and second switch 322 (e.g., pass transistors) may be open circuited, and the second transistor 352 may be enabled to short the gate of the first transistor 354, causing the first transistor 354 to open circuit. This procedure may disconnect the thermal sense module 312 from the fluidic die circuitry 318. During a thermal measurement, the selection switch 334, common mode sense switch 346, common mode control switch 348, first switch 320, and second switch 322 (e.g., pass transistors) for a thermal sense module 312 may be activated, while the second transistor 352 may be disabled (e.g., open circuited), and the common mode control signal 340 may be applied to the gate of the first transistor 354, allowing the first transistor 354 to become part of a feedback path.

In some examples, the first switch 320 and the second switch 322 may be activated to output voltages for the thermal sense modules 312. In an example, the thermal sense module 312 of FIG. 3B may be the thermal sense module 312a of the fluidic die circuitry 318 of FIG. 3A. In this example, the selection switch 334, the first switch 320, and the second switch 322 may be activated to output a temperature voltage signal 326 for thermal zone A 308a. Other respective selection switches and pairs of first switches and second switches may be activated to output a temperature voltage signal 326 for other thermal sense modules (e.g., for other thermal zones).

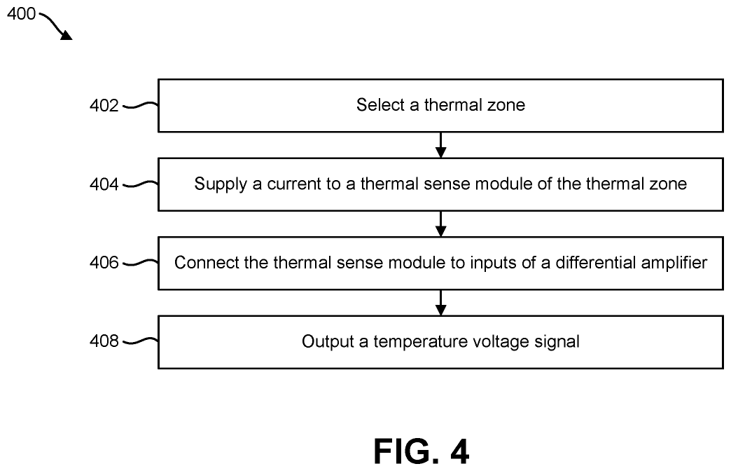

FIG. 4 is a flow diagram illustrating an example of a method 400 for temperature sensing. In some examples, the method 400 may be performed by the fluidic die 106b, the fluid ejection device 104, the fluid ejection system 102, the fluidic die circuitry 218, and/or the fluidic die circuitry 318 described herein.

A fluidic die may select 402 a thermal zone. For example, the fluidic die (e.g., thermal control circuitry) may provide a selection signal to a selection switch of a thermal sense module corresponding to the thermal zone.

The fluidic die may supply 404 a current to a thermal sense module of the thermal zone. For example, a current source may supply the current to the thermal sense module. In some examples, the selection signal may be a voltage to activate the selection switch, which may allow the current from the current source to flow through the selected thermal sense module. As described herein, a first switch and a second switch (e.g., a pair of a plurality of switches) may be coupled to each thermal sense module of the plurality of thermal sense modules. In some examples, the thermal sense module includes a plurality of diodes connected in series, where the current may flow through the diodes.

The fluidic die may connect 406 the thermal sense module to inputs of a differential amplifier. For example, the fluidic die may activate a first switch and a second switch of the plurality of switches. The first switch may be coupled to a first input of a differential amplifier and the second switch may be coupled to a second input of the differential amplifier. For example, activating the first switch may provide a first voltage to a first input of the differential amplifier via the first switch, and activating the second switch may provide a second voltage to a second input of the differential amplifier via the second switch. Accordingly, the fluidic die may connect selected nodes to the differential amplifier. For instance, activating the first switch and the second switch may couple a voltage from across a plurality of diodes to across the first input and the second input of the differential amplifier. Thus, the temperature voltage signal indicates a temperature of the thermal zone.

The fluidic die may output 408, from the differential amplifier, a temperature voltage signal. For example, the differential amplifier may measure a difference between the voltages provided by the switches to output the temperature voltage signal. The temperature voltage signal may indicate the temperature or average temperature corresponding to the selected thermal zone or selected thermal zones (e.g., selected thermal sense module or selected thermal sense modules.

In some examples, the temperature voltage signal may be utilized to make a thermal control decision. For example, the fluidic die 106b, fluid ejection device 104, and/or fluid ejection system 102 may utilize the temperature voltage signal to make a thermal control decision. Some examples of thermal control decisions include activating or deactivating a heater of a zone. For instance, the temperature of a zone may be measured. If the temperature is lower than a defined threshold, then a heater in that zone may be activated to increase the temperature of that zone. If the temperature of the zone is higher than a defined threshold, then the heater for that zone may be deactivated if applicable. If a thermal hot spot is detected, operation (e.g., a fluid dispersion, printing, etc.) may be slowed or stopped.

In some examples, the thermal control circuitry 116, the fluid ejection device 104, and/or the fluid ejection system 102 described in connection with FIG. 1B may make a thermal control decision based on the temperature voltage signal. For example, the temperature voltage signal may be provided to an analog-to-digital converter (ADC) in the thermal control circuitry 116, the fluid ejection device 104, or the fluid ejection system 102, which may convert the temperature voltage signal to a digital signal, which may indicate or be utilized to determine a temperature. The temperature may be compared to one or more thresholds to make the temperature control decision.

In some examples, the method 400 may include determining whether to measure the temperature of another zone. For example, if measurement of a sequence of zones is not complete, the method 400 may include selecting another thermal zone and outputting a temperature voltage signal corresponding to that zone. This may be done until the sequence of zone measurements is complete.

In some examples, an average temperature from multiple thermal zones may be determined. For example, the current of a current source may be set to a level for a multi-zone measurement. Multiple thermal zones may be selected for measurement. The current may be forced into the thermal sense modules (e.g., diode stacks or diode-connected transistors) corresponding to the selected thermal zones. The first and second switches of each of the selected thermal zones may be activated to couple the selected thermal sense modules to the inputs of the differential amplifier, which may produce the average temperature voltage signal. The average temperature voltage signal may be utilized to make a thermal control decision in some examples.

In some examples, the thermal control circuitry 116, the fluid ejection device 104, and/or the fluid ejection system 102 described in connection with FIG. 1B may make a thermal control decision based on the temperature voltage signal. For example, the temperature voltage signal may be provided to an ADC in the thermal control circuitry 116, the fluid ejection device 104, or the fluid ejection system 102, which may convert the temperature voltage signal to a digital signal, which may indicate or be utilized to determine a temperature. The temperature may be compared to one or more thresholds to make the temperature control decision.

Some examples of the approaches for thermal sensing described herein may be beneficial. For example, voltage amplifiers that are used within thermal zones may be small for cost reasons. Small devices may have significant process induced variations, resulting in offset errors in the voltages they output, and therefore errors in the determined temperature of a zone. Some approaches to reduce the variations may include increasing amplifier size (which may increase cost and implementation area), reducing a range of amplifier operation (which may reduce flexibility), and calibrating by determining amplifier error for each thermal sensor and correcting measurements with the error (which may increase complexity). Some benefits of the examples described herein may include significant temperature offset error reduction (for measuring thermal zone temperatures without significantly increasing circuitry size, for instance). Some examples may allow thermal sensing to operate independently of data loading and firing.

1. A fluidic die for temperature sensing, comprising:
a plurality of thermal sense modules, wherein each of the thermal sense modules comprises a diode connected between a first switch and a second switch; and
a differential amplifier to output a temperature voltage signal, wherein a first input of the differential amplifier is connected to the first switch of each of the thermal sense modules and a second input of the differential amplifier is connected to the second switch of each of the thermal sense modules.

2. The fluidic die of claim 1, wherein each of the thermal sense modules corresponds to a thermal zone and the differential amplifier is a single differential amplifier to output a differential voltage for each of the thermal zones.

3. The fluidic die of claim 1, further comprising a single current source to drive the plurality of thermal sense modules.

4. The fluidic die of claim 1, wherein each of the thermal sense modules comprises a selection switch to be activated to force a current through the diode.

5. The fluidic die of claim 1, comprising multiple diodes connected between the first switch and the second switch, and a second diode connected between the second switch and ground.

6. The fluidic die of claim 1, further comprising a fluidic actuator and a fluid chamber for each of the plurality of thermal sense modules.

7. The fluidic die of claim 1, further comprising a plurality of selection switches, wherein a set of the plurality of selection switches corresponding to a selected set of thermal sense modules of the plurality of the thermal sense modules is to be activated to output an average temperature voltage signal over the selected set of thermal sense modules.

8. The fluidic die of claim 7, wherein a current of a current source is to be set based on a number of the selected set of thermal sense modules.

9. The fluidic die of claim 1, wherein the fluidic die is a fluid ejection die.

10. A fluidic die, comprising:
multiple thermal zones, wherein each thermal zone comprises a thermal sense module having a diode-connected transistor;
a pair of switches included in each thermal sense module; and
a differential amplifier, wherein a pair of inputs of the differential amplifier is coupled to each pair of switches, and wherein the differential amplifier is to output a temperature voltage signal for each thermal zone.

11. The fluidic die of claim 10, further comprising a feedback amplifier, a common mode control switch, and a common mode sense switch.

12. The fluidic die of claim 11, further comprising a second diode-connected transistor coupled in series with the diode-connected transistor, wherein the common mode sense switch is coupled between the second diode-connected transistor and the diode-connected transistor.

13. A method for temperature sensing by a fluidic die, comprising:
selecting a thermal zone;
supplying a current to a thermal sense module of the thermal zone, wherein a first switch and a second switch are coupled to the thermal sense module;
activating the first switch and the second switch to connect the thermal sense module to a differential amplifier, wherein the first switch is coupled to a first input of the differential amplifier and the second switch is coupled to a second input of the differential amplifier; and
outputting, from the differential amplifier, a temperature voltage signal.

14. The method of claim 13, wherein the thermal sense module comprises a plurality of diodes connected in series.

15. The method of claim 14, wherein activating the first switch and the second switch couples a voltage from across the plurality of diodes to across the first input and the second input of the differential amplifier, and wherein the temperature voltage signal indicates a temperature of the thermal zone.
